(19) United States
(12) Patent Application Publication
(10) Pub. No.: US 2025/0212588 A1
(43) Pub. Date: Jun. 26, 2025

(54) MICRO-LED DISPLAY PANEL AND MICRO DISPLAY SYSTEM

(71) Applicant: JADE BIRD DISPLAY (SHANGHAI) LIMITED, SHANGHAI (CN)

(72) Inventor: Shuai ZHANG, Shanghai (CN)

(21) Appl. No.: 18/985,504

(22) Filed: Dec. 18, 2024

(30) Foreign Application Priority Data
Dec. 22, 2023 (WO) PCT/CN2023/140914

(51) Int. Cl. H10H 29/855; H10H 29/80

(52) U.S. Cl. CPC H10H 29/855; H10H 29/942

(57) ABSTRACT

A micro-LED display panel includes a micro-LED display chip including a micro-LED array area and an IC (integrated circuit) backplane, wherein the micro-LED array area is provided on the IC backplane; an image light rotating element including a transmission lens assembly provided above the micro-LED display chip and including a transmission lens over the micro-LED array area; and a lens position rotating actuator configured to rotate the transmission lens about at least one preset axis, wherein the at least one preset axis is parallel to the micro-LED array area; and a holder provided on the micro-LED display chip and configured to support the transmission lens assembly.

### CROSS-REFERENCE TO RELATED APPLICATIONS

The present disclosure claims the benefits of priority to PCT Application No. PCT/CN2023/140914, filed on Dec. 22, 2023, which is incorporated herein by reference in its entirety.

### TECHNICAL FIELD

The present disclosure generally relates to micro-LED technology, and more particularly, to a micro-LED display panel and a micro display system.

### BACKGROUND

A self-emitting micro-LED display panel includes a micro-LED (light emitting diode) array and an IC (integrated circuit) backplane that is connected with each of the micro-LEDs as pixels in the micro-LED array for image display. A diameter of the micro-LED can be made to be less than 5 microns by present semiconductor technology, so that the integrity and image quality of the display panel is improved compared with a conventional display panel, such as an LCD (liquid crystal display).

When a micro-LED is used with an optical lens for product design and application, the resolution of the product depends on the resolution of the micro-LED display panel. Once the resolution of the micro-LED is determined, the resolution for product has been determined and cannot be changed.

### SUMMARY OF THE DISCLOSURE

In order to overcome the drawback mentioned above, the present disclosure provides a micro-LED display panel and a micro display system with a transmission lens, configured to improve the resolution for micro-LED display panel.

Embodiments of the present disclosure provide a micro-LED (light emitting diode) display panel. The micro-LED display panel includes a micro-LED display chip including a micro-LED array area and an IC (integrated circuit) backplane, wherein the micro-LED array area is provided on the IC backplane; an image light rotating element including a transmission lens assembly provided above the micro-LED display chip and including a transmission lens over the micro-LED array area; and a lens position rotating actuator configured to rotate the transmission lens about at least one preset axis, wherein the at least one preset axis is parallel to the micro-LED array area; and a holder provided on the micro-LED display chip and configured to support the transmission lens assembly.

Embodiments of the present disclosure provide a micro-LED (light emitting diode) display panel. The micro-LED display panel includes a micro-LED display chip including a micro-LED array area and an IC (integrated circuit) backplane, wherein the micro-LED array area is provided on the IC backplane; an image light rotating element including a transmission lens assembly provided above the micro-LED display chip and including a transmission lens over the micro-LED array area; and a lens position rotating actuator configured to rotate the transmission lens about at least one preset axis, wherein the at least one preset axis is parallel to the micro-LED array area; an external circuit plane provided at a bottom of the IC backplane and electrically connected with the IC backplane via a bonding wire; and a holder provided on the external circuit plane and configured to support the transmission lens assembly.

Embodiments of the present disclosure further provide a micro display system. The micro display system includes the above-described micro-LED display panel and a controlling unit connected with the IC backplane and the image light rotating elements of the micro-LED display panel and configured to transmit objective image data to the IC backplane and the image light rotating element.

Many other advantages and features of the present disclosure will be further understood by the following detailed descriptions and the appended drawings.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1A is a structural view of an exemplary micro-LED display panel without an image light rotating element, according to some embodiments of the present disclosure.

FIG. 1B is a top view of an exemplary micro-LED display panel without an image light rotating element shown in FIG. 1A, according to some embodiments of the present disclosure.

FIG. 2A is a structural view of an exemplary micro-LED display panel with an image light rotating element, according to some embodiments of the present disclosure.

FIG. 2B is a top view of an exemplary micro-LED display panel with an image light rotating element shown in FIG. 2A, according to some embodiments of the present disclosure.

FIG. 3 is a top view of an exemplary micro-LED display panel without a transmission lens assembly, according to some embodiments of the present disclosure.

FIG. 4 is a schematic illustration of an exemplary transmission lens assembly, according to some embodiments of the present disclosure.

FIG. 5 illustrates an exemplary rotating transmission lens configured to rotate about an X axis, according to some embodiments of the present disclosure.

FIG. 6 illustrates an exemplary rotating transmission lens configured to rotate about a Y axis, according to some embodiments of the present disclosure.

FIG. 7 is a schematic illustration of an exemplary micro display system, according to some embodiments of the present disclosure.

FIG. 8 illustrates a pixel area of a micro-LED array, according to some embodiments of the present disclosure.

FIG. 9 illustrates positions of pixel sub-images shifting from an objective pixel point in the pixel area, according to some embodiments of the present disclosure.

FIG. 10 illustrates an objective image formed by objective image data, according to some embodiments of the present disclosure.

FIG. 11 illustrates a position of each of sub-images shifting from an objective image, according to some embodiments of the present disclosure.

FIG. 12 illustrates the positions of the sub-images shifting from the objective image, according to some embodiments of the present disclosure.

FIG. 13 illustrates a formula relationship between a shifting distance of the sub-image from the objective image and a rotation angle of a transmission lens based on an axis, according to some embodiments of the present disclosure.

FIG. 14A and FIG. 14B illustrate flow charts of micro-LED image displaying methods, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

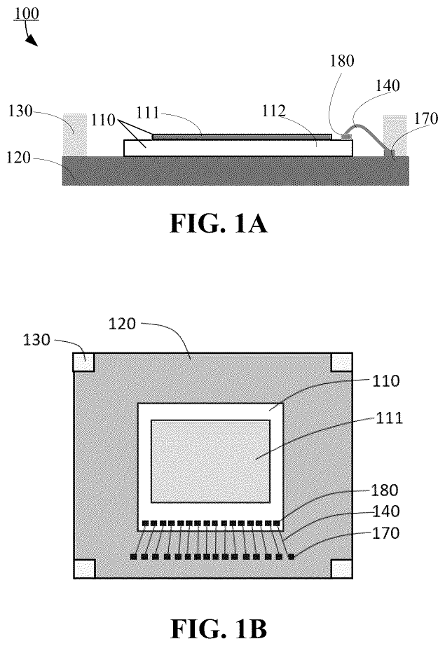

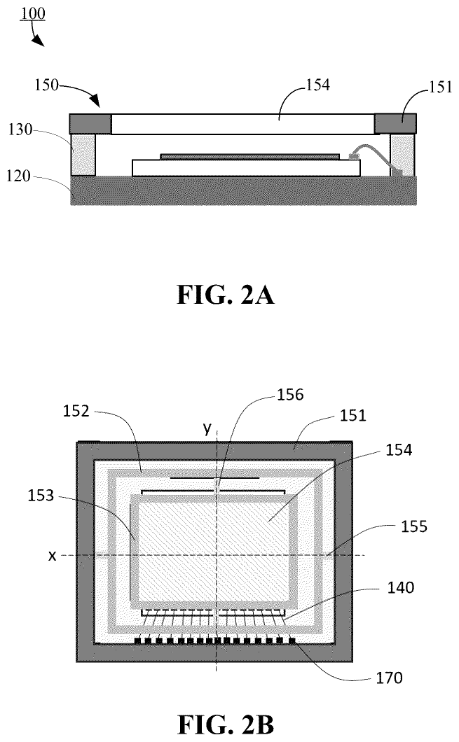

FIG. 1A is a structural view of an exemplary micro-LED display panel 100 without an image light rotating element, according to some embodiments of the present disclosure. FIG. 1B is a top view of micro-LED display panel 100 without an image light rotating element shown in FIG. 1A, according to some embodiments of the present disclosure. FIG. 2A is a structural view of micro-LED display panel 100 with an image light rotating element, according to some embodiments of the present disclosure. FIG. 2B is a top view of micro-LED display panel 100 with an image light rotating element shown in FIG. 2A, according to some embodiments of the present disclosure. FIG. 3 is a top view of micro-LED display panel 100 without a transmission lens assembly, according to some embodiments of the present disclosure. Referring to FIGS. 1A-1B, FIGS. 2A-2B and FIG. 3, micro-LED display panel 100 includes a micro-LED display chip 110, an external circuit plane 120, a holder 130, and an image light rotating element. Micro-LED display chip 110 is provided on external circuit plane 120. The micro-LED display chip 110 includes a micro-LED array area 111 and an IC (integrated circuit) backplane 112. Micro-LED array area 111 is located on IC backplane 112 to form an image display area of micro-LED display chip 110. The rest of the area on IC backplane 112 not covered by micro-LED array area 111 is formed as a non-functional area. In some embodiments, holder 130 is provided on external circuit plane 120. In some embodiments, holder 130 is provided on the non-functional area of IC backplane 112. In some embodiments, external circuit plane 120 is made by a flexible printed circuit.

Micro-LED array area 111 further includes one or more micro-LEDs, each of which is connected with the IC backplane 112 respectively. Micro-LED display panel 100 further includes bonding wires 140. IC backplane 112 is conductively connected with external circuit plane 120 by bonding wires 140. In some embodiments, bonding wires 140 connect pads 180 on IC backplane 112 with pads 170 of external circuit plane 120 for connecting the one or more micro-LEDs.

The image light rotating element includes transmission lens assembly 150 (FIG. 2A) and a lens position rotating actuator 160 (FIG. 3). Transmission lens assembly 150 is supported by holder 130 and covers micro-LED display chip 110. Transmission lens assembly 150 includes a transmission lens 154 facing micro-LED array area 111. Lens position rotating actuator 160 is configured to rotate transmission lens 154 about at least one preset axis. In some embodiments, the at least one preset axis is parallel with micro-LED array area 111. An area of transmission lens 154 covers an area of micro-LED array area 111. In some embodiments, the area of transmission lens 154 covers an area of micro-LED display chip 110. In some embodiments, holder 130 connects an edge of transmission lens assembly 150 and an edge of external circuit plane 120 or an edge of IC backplane 112. In some embodiments, referring to FIG. 3, holder 130 includes a plurality of pillars arranged at each corner of external circuit plane 120.

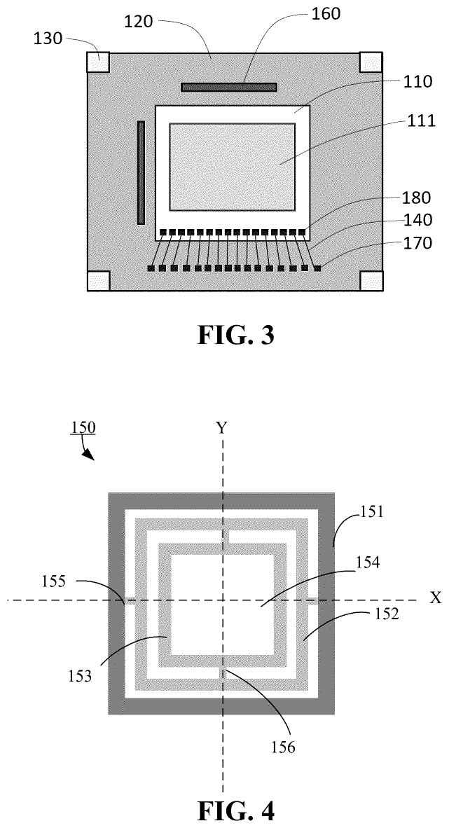

FIG. 4 is a schematic illustration of an exemplary transmission lens assembly 150, according to some embodiments of the present disclosure. As shown in FIG. 4, transmission lens assembly 150 includes a first frame 151, a second frame 152, a third frame 153, and transmission lens 154. Second frame 152 is provided inside first frame 151, and third frame 153 is provided inside second frame. That is, a size of second frame 152 is smaller than a size of first frame 151, and a size of third frame 153 is smaller than a size of second frame 152. Transmission lens 154 is supported by third frame 153. The preset axis includes an X-axis and a Y-axis. First frame 151 is coupled to second frame 152 by a first pair of connecting bridge 155 along a first direction, for example, an X-axis direction shown in FIG. 4. Thus, second frame 152 can be rotated about the X-axis. Second frame 152 is coupled to third frame 153 by a second pair of connecting bridge 156 along a second direction, for example, a-Y axis direction shown in FIG. 4. Thus, third frame 153 can be rotated about the Y-axis. When third frame 153 rotates about the Y-axis, transmission lens 154 can be rotated with third frame 153 about the Y-axis. When second frame 152 rotates about the X-axis, third frame 153 can be rotated with second frame 152 by second pair of connecting bridge 156. Therefore, transmission lens 154 can be rotated with third frame 153 (together with second frame 152) about the X-axis. In some embodiments, second frame 152 and third frame 153 include magnetic materials. For example, second frame 152 and third frame 153 can be configured as ferromagnetic frames. In some embodiments, transmission lens 154 is transparent. For example, a material of transmission lens 154 can be inorganic-glass or resin glass. In some embodiments, transmission lens 154 is an optical lens. Image light emitted from micro-LED array area 111 passes through transmission lens 154 and is transmitted through transmission lens 154 in a changeable direction corresponding to a rotating direction of transmission lens 154 about the X-axis and/or the Y-axis.

Referring to FIG. 3, in some embodiments, lens position rotating actuator 160 includes one or more magnetic elements, each of which can generate a magnetic field for controlling rotation of second frame 152 and third frame 153, thereby controlling rotation of transmission lens 154.

In some embodiments, the one or more magnetic elements are disposed on IC backplane 112 and under an edge of first frame 151. In some embodiments, each of the magnetic elements is controlled by applying a voltage thereto. For example, when applying voltages, a first magnetic element is configured to generate a first magnetic field, and a second magnetic element is configured to generate a second magnetic field. The first magnetic field is perpendicular to the second magnetic field. As a result, the first magnetic element and the second magnetic element can control transmission lens 154 to rotate about two mutually perpendicular preset directions. More particularly, for example, the first magnetic element is configured to control second frame 152 to rotate about the X-axis, and the second magnetic element is configured to control third frame 153 to rotate about the Y-axis. The first magnetic element is provided corresponding to an edge of second frame 152 parallel to the X-axis. The second magnetic element is provided corresponding to an edge of third frame 153 parallel to the Y-axis. Therefore, when the first magnetic element generates a magnetic field for controlling second frame 152, second frame 152 rotates about the X-axis. When the second magnetic element generates a magnetic field for controlling third frame 153, third frame 153 rotates about the Y-axis. In some embodiments, the image light rotating element further includes an actuator controller coupled to lens position rotation actuator 160 to control generation of the magnetic fields, thereby controlling a rotation direction and a rotating frequency of transmission lens 154.

In some embodiments, first frame 151 is a rigid frame and is supported by holder 130. Holder 130 is configured to support transmission lens assembly 150 by supporting first frame 151. First frame 151 is connected with IC backplane 112 or with external circuit plane 120 by holder 130.

The one or more magnetic elements are provided between transmission lens assembly 150 and micro-LED display panel 100. In some embodiments, when holder 130 is provided on IC backplane 112, the first magnetic element is provided on a first edge of IC backplane 112 and corresponds to an edge of second frame 152. The second magnetic element is provided on a second edge of IC backplane 112 and corresponds to an edge of third frame 153. The first edge of IC backplane 112 is perpendicular to the second edge. Alternatively, in some embodiments, when holder 130 is provided on external circuit plane 120, the first magnetic element is provided on a first edge of external circuit plane 120 and corresponds to an edge of second frame 152. The second magnetic element is provided on a second edge of external circuit plane 120 and corresponds to an edge of third frame 153. The first edge of external circuit plane 120 is perpendicular to the second edge. In some embodiments, the first magnetic element and the second magnetic element are provided under transmission lens assembly 150. In some embodiments, holder 130 is provided separated from the one or more magnetic elements. That is, holder 130 and the one or more magnetic elements are not in contact.

In some embodiments, the one or more magnetic elements are electromagnetic coils or capacitance magnetic elements.

In some embodiments, micro-LED display chip 110 can be an AM (active matrix) micro-LED display chip or a PM (passive matrix) micro-LED display chip.

Transmission lens 154 is arranged facing micro-LED array area 111, consistent with FIG. 2A. In some embodiments, a distance between a bottom of transmission lens 154 and a top of micro-LED array area 111 is not less than 1 μm. Lens position rotating actuator 160 is configured to control transmission lens 154 to rotate about at least one preset axis. In some embodiments, the preset axis is parallel to micro-LED array area 111. In some embodiments, as shown in FIG. 4, the preset axis includes the X-axis and the Y-axis. When transmission lens 154 is rotated, transmission lens 154 cannot contact the surface of micro-LED array area 111. Accordingly, a top of holder 130 is higher than a top of the micro-LED display panel (e.g., a top of micro-LED array area 111).

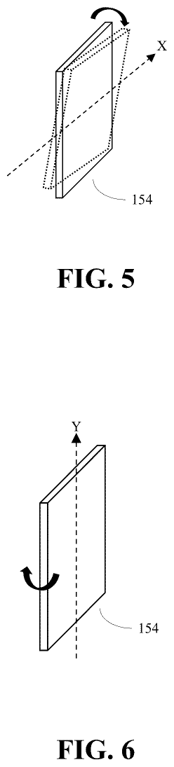

FIG. 5 illustrates transmission lens 154 configured to rotate about the X-axis, according to some embodiments of the present disclosure. Referring to FIG. 5, transmission lens 154 can be rotated about the X-axis by a lens position rotating actuator (e.g., lens position rotating actuator 160 in FIG. 3).

FIG. 6 illustrates transmission lens 154 configured to rotate about the Y-axis, according to some embodiments of the present disclosure. Referring to FIG. 6, transmission lens 154 can further be rotated about the Y-axis by the lens position rotating actuator (e.g., lens position rotating actuator 160 in FIG. 3). As disclosed herein, the Y-axis is parallel to the micro-LED array area in a second direction. The first direction is not parallel with the second direction. In some embodiments, the first direction is perpendicular to the second direction, so the X-axis is perpendicular to the Y-axis. For example, the X-axis is along a horizontal direction and the Y-axis is along a vertical direction, as viewed in FIG. 5 and FIG. 6.

Referring to FIG. 5 and FIG. 6, rotation angles of transmission lens 154 can be designated +X° (about the X-axis), −X° (about the X-axis), +Y° (about the Y-axis) and −Y° (about the Y-axis). In some embodiments, X° is not more than 15°, and Y° is not more than 15°. In a three-dimensional space, the rotation angles of transmission lens 154 can be (−X°, +Y°), (+X°, +Y°), (+X°, −Y°) and (−X°, −Y°).

In some embodiments, micro-LED display panel 100 further includes an actuator controller electrically connected to lens position rotating actuator 160 for controlling lens position rotating actuator 160 to further control a rotation direction and rotating frequency of transmission lens 154. As a result, transmission lens 154 can be rotated at various angle about the X-axis and/or Y-axis, and the emitting light of each of pixels of micro-LED display panel 100 can be shifted at various positions to increase the resolution ratio of the pixels.

The micro-LED display panel with a transmission lens assembly can provide a changeable resolution with the rotation of the transmission lens, and thereby improve the efficiency.

In some embodiments, micro-LED display panel 100 is applied in micro display devices or micro sensors, for example, a near-eye display, an augmented reality (AR) display, a virtual reality (VR) display, a Head Up/Head Mount or other displays, a micro three-dimensional printing device, etc.

In some embodiments, a diagonal length of micro-LED display panel 100 is not greater than 5 μm. In some embodiments, a diagonal length of micro-LED array area 111 is not greater than 5 cm. In some embodiments, an area of micro-LED array area 111 is not greater than 1 cm². In some embodiments, a diagonal length of transmission lens 154 is not less than a diagonal length of micro-LED array area 111.

In some embodiments, a micro display system is further provided. The micro display system includes a micro-LED display panel and a controlling unit. The controlling unit is electrically connected to the micro-LED display panel for controlling a display.

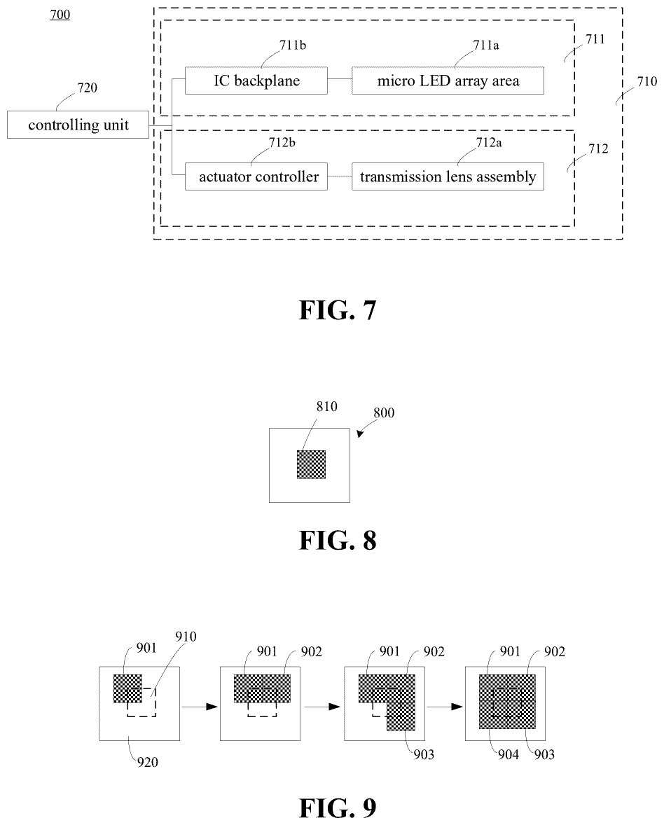

FIG. 7 illustrates a schematic illustration of an exemplary micro display system 700, according to some embodiments of the present disclosure. Referring to FIG. 7, the micro-LED display panel as discussed above can be applied in micro display system 700. Micro display system 700 includes a micro-LED display panel 710 and a controlling unit 720. Controlling unit 720 is connected to a micro-LED display chip 711 and an image light rotating element 712. Micro LED display chip 711 includes a micro-LED array area 711a and an IC (integrated circuit) backplane 711b that is formed by, e.g., metal-bonding at the bottom of micro-LED array area 711a and electrically connected with each of micro-LEDs of micro-LED array area 711a. Image light rotating element 712 includes a transmission lens assembly 712a and an actuator controller 712b. Controlling unit 720 is connected to IC backplane 711b and actuator controller 712b for transmitting signals to IC backplane 711b and actuator controller 712b. Controlling unit 720 is configured to process objective image data to form N pieces of sub-image data and calculate a rotation direction and rotating frequency of transmission lens assembly 712a for each sub-image data according to a refresh frequency of the objective image data, send the rotation direction and rotating frequency to actuator controller 712b, and send the sub-image data and the rotating frequency to IC backplane 711b. Actuator controller 712b is configured to receive the rotation direction and the rotating frequency of transmission lens assembly 712a for each sub-image data. Actuator controller 712b is further configured to control a lens position rotating actuator (not shown) and transmission lens assembly 712a to perform a rotating process based on the rotation direction and the rotating frequency for each sub-image data. IC backplane 711b is configured to synchronously control micro-LED display chip 711 to display a sub-image according to the sub-image data and the rotating frequency.

The sub-image, the shifting position of the sub-image, and relationship between the rotation of the transmission lens and the shifting position of the sub-images are disclosed in further detail as follows.

Each pixel point in micro-LED array area 711a is separately formed in a corresponding pixel area, and each pixel area comprises N pieces of pixel sub-images. The pixel sub-image of a pixel point is shifted in a shifting order and in the pixel area of the pixel point. The N pieces of sub-images are shifted in a same shifting order with the sub-images, wherein N is an integer and not less than two. The rotating frequency of sub-image data is M times a refresh frequency of the objective image data, wherein M is an integer and not less than two. In some embodiments, M is equal to N. In some embodiments, M is an even integer. In some embodiments, the shifting direction is a clockwise direction. A refresh frequency of the objective image data is 50˜70 Hz. In some embodiments, M is not an integer and can be less than 1, for example, 0.5.

FIG. 8 illustrates an exemplary pixel area 800 of a micro-LED array, e.g., micro-LED array area 711a, according to some embodiments of the present disclosure. Referring to FIG. 8, one initial pixel image without rotation of the transmission lens is illustrated. As shown in FIG. 8, the large block illustrates pixel area 800 and the small block illustrates a pixel point 810 of pixel area 800 as a stippled small block. FIG. 9 illustrates exemplary positions of pixel sub-images shifting from the objective pixel point in the pixel area, according to some embodiments of the present disclosure. Referring to FIG. 9, pixel sub-images with the rotating of the transmission lens are illustrated. As shown in FIG. 9, the stippled small block represents the initial pixel point without being shifted in an objective image produced from the objective image data. The pixel area includes a first pixel sub-image 901 of the pixel point, a second pixel sub-image 902 of the pixel point, a third pixel sub-image 903 of the pixel point, and a fourth pixel sub-image 904 of the pixel point. First pixel sub-image 901 is shifted left-up in the pixel area relative to a pixel point 910 (the stippled block) in an objective image 920. Second pixel sub-image 902 is shifted right-up in the pixel area relative to pixel point 910 in the objective image. Third pixel sub-image 903 is shifted right-down in the pixel area relative to pixel point 910 in the objective image. Fourth pixel sub-image 904 is shifted left-down in the pixel area relative to pixel point 910 in the objective image.

As disclosed herein, in some embodiments, a rotating frequency of the transmission lens is four times a refresh frequency of the objective image data. The rotation angle of the transmission lens is (−X°, +Y°), (+X°, +Y°), (+X°, −Y°), (−X°, −Y°) in order, so the sub-images corresponding to each of the rotation angles are displayed from left to right and from up to down in a clock-wise direction.

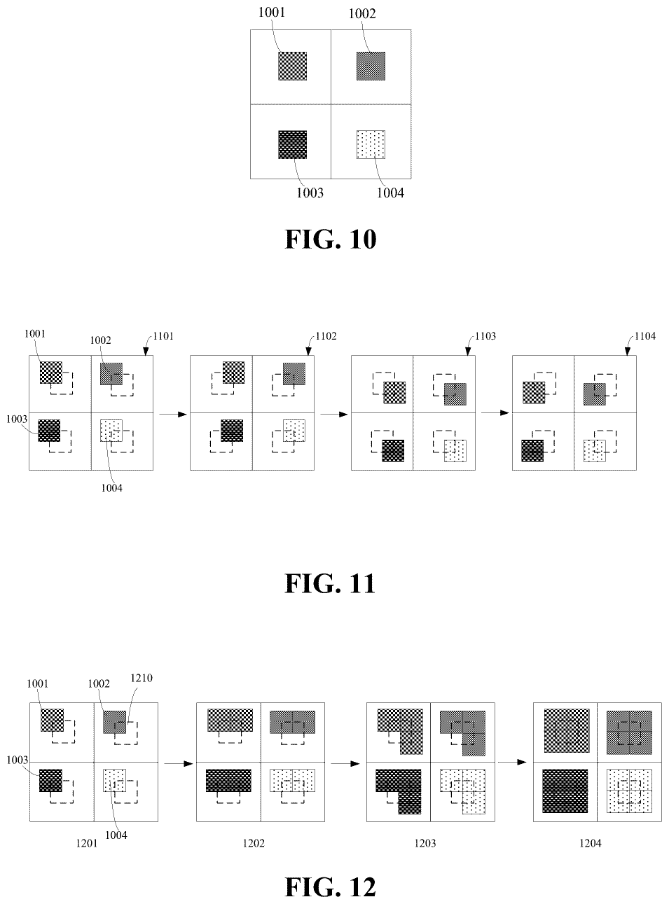

FIG. 10 illustrates an objective image formed by objective image data, according to some embodiments of the present disclosure. Referring to FIG. 10, an objective image is formed by different gray-scale values of a micro-LED array, e.g., micro-LED array area 711a. The micro-LED array of a micro-LED display panel, e.g., micro-LED display panel 100, is an M×N matrix, where M is a positive integer greater than 2 and N is a positive integer greater than 2. In some embodiments, the micro-LED array is a 1280×680 matrix. As shown in FIG. 10, four-pixel points (e.g., 1001 to 1004) correspond to four micro-LEDs, which only exemplify the micro-LED array for describing the objective image and sub-images, and are not used to limit the scope of the present disclosure. In some embodiments, a width or a length of the micro-LED display panel is not greater than 5 μm, and a diagonal length of the micro-LED array area is not greater than 5 cm. Therefore, the micro-LED display panel can be designed in a small size.

FIG. 11 illustrates an exemplary position of each of the sub-images shifting relative to the pixel point in the objective image, according to some embodiments of the present disclosure. Referring to FIG. 11, the objective image data is processed to form sub-image data of four sub-images: a first sub-image 1101, a second sub-image 1102, a third sub-image 1103, and a fourth sub-image 1104. As shown in FIG. 11, the stippled blocks represent the pixel point of each sub-image in the objective image. The sub-images 1101-1104 formed by the sub-image data are separately shown in FIG. 11.

Referring to FIG. 9 and FIG. 11, each of the pixel areas includes first pixel sub-image 901, second pixel sub-image 902, third pixel sub-image 903, and fourth pixel sub-image 904. First pixel sub-image 901 is shifted left-up in the pixel area relative to the pixel point in the objective image; second pixel sub-image 902 is shifted right-up in the pixel area relative to the pixel point in the objective image; third pixel sub-image 903 is shifted right-down in the pixel area relative to the pixel point in the objective image; and fourth pixel sub-image 904 is shifted left-down in the pixel area relative to the pixel point in the objective image. Therefore, first sub-image 1101 is shifted left-up in the objective image area relative to the objective image; second sub-image 1102 is shifted right-up in the objective image area relative to the objective image; third sub-image 1103 is shifted right-down in the objective image area relative to the objective image; and fourth sub-image 1104 is shifted left-down in the objective image area. The objective image area is the same as the micro-LED array area and not changed in the displaying process.

As shown in FIG. 11, the positions of the sub-images are shifted from left to right and from up to down in a clockwise direction with the rotation of the transmission lens at the rotating angles of (−X°, +Y°), (+X°, +Y°), (+X°, −Y°), (−X°, −Y°) in order. That is, the position of the sub-image is shifted by rotating the transmission lens, and the position of the sub-image is determined by the rotating angle of the transmission lens. In some embodiments, the sub-images formed by the sub-image data are the same as the objective image formed by the objective image data, thereby ensuring the quality of the displayed objective image. Furthermore, the gray-scale values of all of the pixel sub-images of the same pixel point are the same as the gray-scale values of the objective image of the same pixel point in the objective image data, as shown in FIG. 11. In another example, the gray-scale value of at least one of the pixel sub-images of the same pixel point is not the same as the gray-scale of the objective image of the same pixel point in the objective image data. In some embodiments, one pixel corresponds to one micro-LED.

FIG. 12 illustrates the positions of the sub-images shifting relative to the objective image, according to some embodiments of the present disclosure. The controlling unit (e.g., controlling unit 720 in FIG. 7) is configured to send the sub-image data of the four sub-images and the rotating frequency to the IC backplane and send the rotation angles and the rotating frequency to the actuator controller. Referring to FIG. 12, the dashed-line blocks (for example, 1210) represent the pixel point of the objective image. The actuator controller (e.g., actuator controller 712b in FIG. 7) controls the transmission lens rotating at the rotating angles of (−X°, +Y°) based on the rotating frequency, such as 240 Hz, and the IC backplane (e.g., IC backplane 711b in FIG. 7) controls the micro LED display panel displaying the first sub-image based on the rotating frequency, as shown in a first objective image 1201. The actuator controller controls the transmission lens rotating at the rotating angles (+X°, +Y°) based on the rotating frequency, and the IC backplane controls the micro LED display panel displaying the second sub-image based on the rotating frequency as shown in a second objective image 1202. Similarly displaying of the third sub-image is shown in a third objective image 1203 and similarly displaying of the fourth sub-image is shown in a fourth objective image 1204. Because the rotating frequency is very fast, the human eye cannot see transmitting of the four sub-images and only sees a final objective image as shown in fourth objective image 1204 in FIG. 12, which is similar to the picture shown in FIG. 10. The four sub-images are combined together in the clockwise direction to form the final objective image shown in fourth objective image 1204.

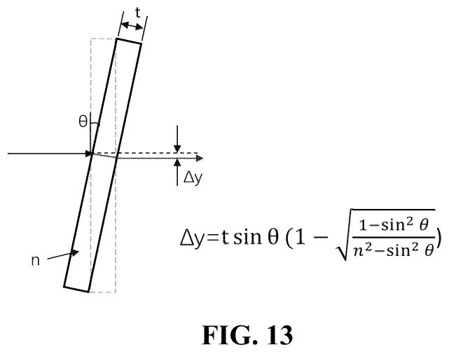

FIG. 13 illustrates a formula relationship between a shifting distance of the sub-image from the objective image and a rotation angle of the transmission lens based on an axis, according to some embodiments of the present disclosure. Referring to FIG. 13, the relationship of the shifting distance and the rotation angle is as follows:

$$Δ y = t sin θ ( 1 - \sqrt{\frac{1 - {sin}^{2} θ}{{n}^{2} - {sin}^{2} θ}} ) ;$$

wherein Δy is the shifting distance, θ is the rotation angle, t is a center thickness of the transmission lens, and n is a refraction ratio of the transmission lens. In some embodiments, the shifting distance between the adjacent pixel sub-images is, for example, 50˜100% of the pixel pitch. Therefore, the rotation angle can be calculated by the above formula.

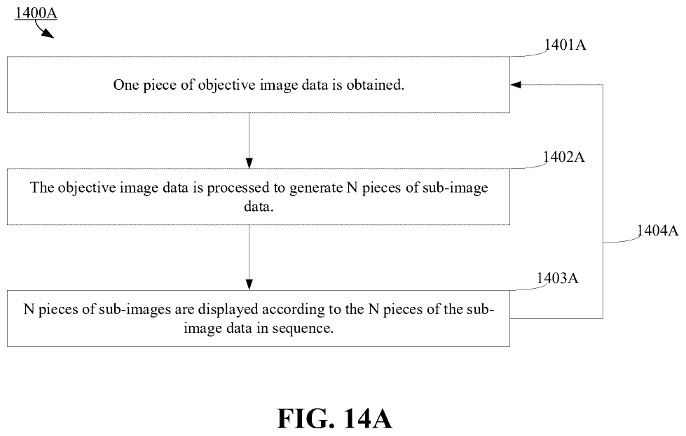

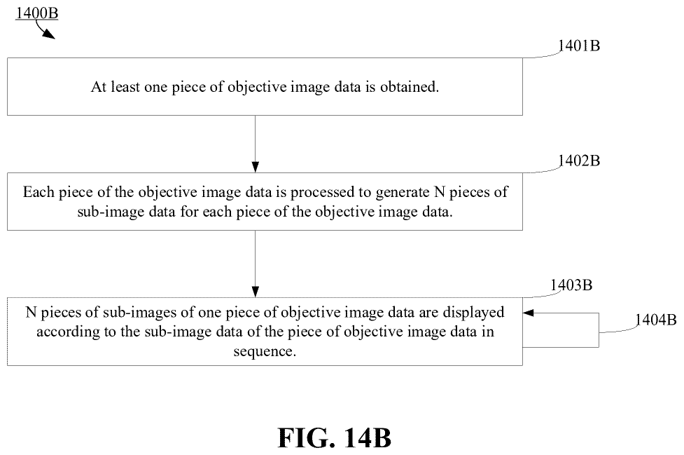

FIG. 14A is a flow chart illustrating a micro-LED image displaying method 1400A, according to some embodiments of the present disclosure. Referring to FIG. 14A, micro-LED image displaying method 1400A using the aforementioned micro-LED display panel includes the following steps 1401A to 1404A.

At step 1401A, one piece of objective image data is obtained. The objective image data can be obtained by a controlling unit, e.g., controlling unit 720, for further operation. In some embodiments, the objective image data can be stored in a memory and can be obtained by the controlling unit via a network. In some embodiments, the memory is an external memory.

At step 1402A, the objective image data is processed to generate N pieces of sub-image data, wherein N is not less than two. For example, four pieces of sub-image data are generated. The four pieces of sub-image data are the same, and the four sub-images formed according to the sub-image data are the same, as shown in FIG. 10.

At step 1403A, N pieces of sub-images are displayed according to the N pieces of the sub-image data in sequence based on the rotating frequency and the preset rotation direction of the transmission lens for each piece of sub-image data, wherein N is an integer and not less than two. Furthermore, a pixel sub-image of a pixel point is shifted in a shifting order and in the pixel area of the pixel point, and the N-piece sub-images are shifted in a same shifting order with the pixel sub-images. The rotating frequency of sub-image data is M times the refresh frequency of the objective image data. In some embodiments, N is an integer not less than two and M is an integer not less than two. In some embodiments, M is equal to N. In some embodiments, M is an even integer. For example, the rotating frequency of the transmission lens is four times the refresh frequency of the objective image data. The refresh frequency of the objective image data is, for example, 50˜70 Hz. In this example, the shifting direction is a clockwise direction. The sub-images formed by the sub-image data are the same as the objective image formed by the objective image data.

In some embodiments, the actuator controller is configured to control the transmission lens rotating at the rotating angles of (−X°, +Y°) based on the rotating frequency, such as 240 Hz, and the IC backplane is configured to control the micro-LED display panel displaying the first sub-image 1101 based on the rotating frequency as shown FIG. 11. The actuator controller is configured to control the transmission lens rotating at the rotating angles (+X°, +Y°) based on the rotating frequency and the IC backplane is configured to control the micro-LED display panel displaying the second sub-image 1102 based on the rotating frequency as shown in FIG. 11. Similarly displaying of the third sub-image 1103 and similarly displaying of the fourth sub-image 1104 are also shown in FIG. 11.

In some embodiments, the IC backplane includes an IC driver circuit to drive each of the micro-LEDs. In some embodiments, the IC driver circuit is driven and controlled by a PWM (pulse width modulation) signal and a current source. In some embodiments, a gray-scale value of each of the micro-LEDs is controlled by the PWM signal.

Referring back to FIG. 14A, at step 1404A, the steps 1401A and 1403A are repeated until all of the objective image data is displayed.

For example, a plurality of objective images can be displayed by repeating the steps 1401A to 1403A.

FIG. 14B illustrates another micro-LED image displaying method 1400B, using the aforementioned micro-LED display panel, according to some embodiments of the present disclosure. Method 1400B includes the following steps 1401B to 1404B.

At step 1401B, at least one piece of objective image data is obtained.

At step 1402B, each piece of the objective image data is processed to generate N pieces of sub-image data for each piece of the objective image data.

At step 1403B, N pieces of sub-images of the piece of objective image data are displayed according to the sub-image data of the piece of objective image data in sequence based on the rotating frequency and the preset rotation direction of the transmission lens for each sub-image data, wherein N is an integer and not less than two.

At step 1404B, the sub-images of next objective image data are displayed in sequence by recycling step 1403B until all of the objective image is displayed.

The details of steps 1402B to 1403B can be understood by referring to the description of steps 1402A to 1403A, which will not be repeated herein.

It is understood by those skilled in the art that the micro-LED display panel is not limited by the structure mentioned above, and may include greater or fewer components than those as illustrated, or some components may be combined, or a different component may be utilized.

The embodiments may further be described using the following clauses:

1. A micro-LED (light emitting diode) display panel comprising:
a micro-LED display chip comprising a micro-LED array area and an IC (integrated circuit) backplane, wherein the micro-LED array area is provided on the IC backplane;
an image light rotating element comprising:
   a transmission lens assembly provided above the micro-LED display chip and comprising a transmission lens over the micro-LED array area; and
   a lens position rotating actuator configured to rotate the transmission lens about at least one preset axis, wherein the at least one preset axis is parallel to the micro-LED array area; and
a holder provided on the micro-LED display chip and configured to support the transmission lens assembly.

2. The micro-LED display panel according to clause 1, wherein the holder is provided on the IC backplane.

3. The micro-LED display panel according to clause 2, wherein the holder is configured to support the transmission lens assembly at an edge of the transmission lens assembly.

4. The micro-LED display panel according to any one of clauses 1 to 3, wherein the preset axis is a first axis, wherein the first axis is parallel to the micro-LED array area in a first direction.

5. The micro-LED display panel according to clause 4, wherein the lens position rotating actuator is further configured to rotate the transmission lens about a second axis, wherein the second axis is parallel to the micro-LED array area in a second direction, and the second axis is not parallel to the first axis.

6. The micro-LED display panel according to clause 5, wherein the first axis is perpendicular to the second axis.

7. The micro-LED display panel according to clause 5 or 6, wherein the transmission lens assembly further comprises:
a first frame;
a second frame provided inside the first frame and connected with the first frame by a first pair of connecting bridges along the first axis; and
a third frame provided inside the second frame and connected with the second frame by a second pair of connecting bridges along the second axis;
wherein the transmission lens is supported by the third frame and configured to be rotated with the third frame.

8. The micro-LED display panel according to clause 7, wherein the holder is configured to support the transmission lens assembly by supporting the first frame.

9. The micro-LED display panel according to any one of clauses 1 to 8, wherein, when rotating, the transmission lens and the micro-LED array area do not contact each other.

10. The micro-LED display panel according to clause 9, wherein a distance between a bottom of the transmission lens and a top of micro-LED array area is not less than 1 μm.

11. The micro-LED display panel according to clause 1, wherein the lens position rotating actuator further comprises one or more magnetic elements provided between the transmission lens assembly and the micro-LED chip.

12. The micro-LED display panel according to clause 11, wherein the one or more magnetic elements are provided on the IC backplane and under an edge of the transmission lens assembly.

13. The micro-LED display panel according to clause 12, wherein the transmission lens assembly further comprises:
a first frame;
a second frame provided inside the first frame and connected with the first frame by a first pair of connecting bridges along a first axis; and
a third frame provided inside the second frame and connected with the second frame by a second pair of connecting bridges along a second axis;
wherein the transmission lens is supported by the third frame and configured to be rotated with the third frame.

14. The micro-LED display panel according to clause 13, wherein the one or more magnetic elements are provided under an edge of the first frame.

15. The micro-LED display panel according to clause 14, wherein a first one of the one or more magnetic elements is provided at a first edge of the IC backplane, a second one of the one or more magnetic elements is provided at a second edge of the IC backplane, and the first edge is perpendicular to the second edge.

16. The micro-LED display panel according to clause 14, wherein a first one of the one or more magnetic element is configured to generate a first magnetic field, a second one of the one or more magnetic elements is configured to generate a second magnetic field, wherein the first magnetic field is perpendicular to the second magnetic field.

17. The micro-LED display panel according to clauses 16, wherein the holder and the first and second magnetic elements are spaced apart.

18. The micro-LED display panel according to clause 17, wherein each of the first and second magnetic elements is an electromagnetic coil or a capacitance magnetic element.

19. The micro-LED display panel according to any one of clauses 1 to 18, wherein one or more of the holders are provided at one or more corners of the IC backplane.

20. The micro-LED display panel according to any one of clauses 1 to 19, wherein a top of the holder is higher than a top of the micro-LED array area.

21. The micro-LED display panel according to any one of clauses 1 to 20, wherein the micro-LED display chip is an AM (active matrix) micro-LED display chip or PM (passive matrix) micro-LED display chip.

22. The micro-LED display panel according to any one of clauses 1 to 21, wherein a diagonal length of the micro-LED array area is not greater than 1 cm.

23. The micro-LED display panel according to any one of clauses 1 to 22, wherein a material of the transmission lens is inorganic-glass or resin glass.

24. The micro-LED display panel according to any one of clauses 1 to 23, wherein the micro-LED display panel is applied in a micro display device or a micro sensor.

25. The micro-LED display panel according to any one of clauses 1 to 24, wherein a diagonal length of the micro-LED display panel is not greater than 5 μm; and a diagonal length of the micro-LED array area is not greater than 5 cm.

26. The micro-LED display panel according to any one of clauses 1 to 25, wherein the transmission lens is an optical lens; and image light emitted from the micro-LED array area is transmitted through the transmission lens in a changeable direction corresponding to a rotating direction of the transmission lens.

27. The micro-LED display panel according to any one of clauses 1 to 26, wherein a diagonal length of the transmission lens is not less than a diagonal length of the micro-LED array area.

28. The micro-LED display panel according to any one of clauses 1 to 27, wherein the image light rotating element further comprises an actuator controller electrically connected with the lens position rotating actuator and configured to control a rotation direction and a rotating frequency of the transmission lens.

29. A micro display system comprising:
a micro-LED (light emitting diode) display panel comprising
   a micro-LED display chip comprising a micro-LED array area and an IC (integrated circuit) backplane, wherein the micro-LED array area is provided on the IC backplane;
   an image light rotating element comprising:
      a transmission lens assembly provided above the micro-LED display chip and comprising a transmission lens over the micro-LED array area; and
      a lens position rotating actuator configured to rotate the transmission lens about at least one preset axis, wherein the at least one preset axis is parallel to the micro-LED array area; and
   a holder provided on the micro-LED display chip and configured to support the transmission lens assembly; and
a controlling unit connected with the IC backplane and the image light rotating element of the micro-LED display panel and configured to transmit objective image data to the IC backplane and the image light rotating element.

30. The micro display system according to clause 29, wherein the image light rotating element further comprises an actuator controller electrically connected with the lens position rotating actuator and configured to control a rotation direction and a rotating frequency of the lens position rotating actuator; and
the controlling unit is further connected with the actuator controller, and further configured to transmit signals to the IC backplane and the actuator controller.

31. The micro display system according to clause 29, wherein the controlling unit is further configured to process the objective image data to form N pieces of sub-image data, calculate a rotation direction and a rotating frequency of the transmission lens for each sub-image data according to a refresh frequency of the objective image data, send the rotation direction and the rotating frequency to the actuator controller, and send the sub-image data and the rotating frequency to the IC backplane; wherein N is an integer not less than two;
the actuator controller is configured to receive the rotation direction and the rotating frequency of the transmission lens for each piece of the sub-image data, and control the lens position rotating actuator and the transmission lens to perform a rotating process based on the rotation direction and the rotating frequency for each piece of the sub-image data; and
the IC backplane is configured to synchronously control the micro-LED array area to display a sub-image according to the sub-image data and the rotating frequency.

32. The micro display system according to clause 31, wherein each of pixel points in the micro-LED array area is separately formed in a corresponding pixel area, each of the pixel areas comprises N pieces of pixel sub-images, the pixel sub-images of a pixel point are shifted in a shifting order and in the pixel area of the pixel point, and the N pieces of pixel sub-images are shifted in a same shifting order with the pixel sub-images.

33. The micro display system according to clause 32, wherein the rotating frequency of sub-image data is M times the refresh frequency of the objective image data, wherein M being an integer not less than two.

34. The micro display system according to clause 33, wherein N is an even integer, and M is equal to N.

35. The micro display system according to clause 33 or 34, wherein the rotating frequency of the transmission lens is four times the refresh frequency of the objective image data.

36. The micro display system according to any one of clauses 33 to 35, wherein the refresh frequency of the objective image data is 50˜70 Hz.

37. The micro display system according to any one of clauses 33 to 36, wherein a shifting direction is a clockwise direction.

38. The micro display system according to clause 32, wherein sub-images formed by the sub-image data are the same as the objective image formed by the objective image data.

39. The micro display system according to clause 38, wherein a gray-scale of at least one of the pixel sub-images of the same pixel point is not the same as a gray-scale of the objective image of the same pixel point in the objective image data.

40. The micro display system according to clause 38, wherein a gray-scale of all of the pixel sub-images of the same pixel point is as same as a gray-scale of the objective image of the same pixel point in the objective image data.

41. The micro display system according to clause 38, wherein a relationship of a shifting distance of the sub-image from the objective image and a rotation angle of the transmission lens about an axis is

$$Δ y = t sin θ ( 1 - \sqrt{\frac{1 - {sin}^{2} θ}{{n}^{2} - {sin}^{2} θ}} ) ;$$

wherein Δy is the shifting distance, θ is the rotation angle, t is a center thickness of the transmission lens, and n is a refraction ratio of the transmission lens.

42. The micro display system according to clause 41, wherein the shifting distance between adjacent pixel sub-images is 50˜100% of a pixel pitch.

43. A micro-LED (light emitting diode) display panel comprising:
a micro-LED display chip comprising a micro-LED array area and an IC (integrated circuit) backplane, wherein the micro-LED array area is provided on the IC backplane;
an image light rotating element comprising:
   a transmission lens assembly provided above the micro-LED display chip and comprising a transmission lens over the micro-LED array area; and
   a lens position rotating actuator configured to rotate the transmission lens about at least one preset axis, wherein the at least one preset axis is parallel to the micro-LED array area;
an external circuit plane provided at a bottom of the IC backplane and electrically connected with the IC backplane via a bonding wire; and
a holder provided on the external circuit plane and configured to support the transmission lens assembly.

44. The micro-LED display panel according to clause 43, wherein the external circuit plane comprises a flexible printed circuit.

45. The micro-LED display panel according to clause 43 or 44, wherein the holder is configured to support the transmission lens assembly at an edge of the transmission lens assembly.

46. The micro-LED display panel according to any one of clauses 43 to 45, wherein the preset axis is a first axis, and the first axis is parallel to the micro-LED array area in a first direction.

47. The micro-LED display panel according to clause 46, wherein the lens position rotating actuator is further configured to rotate the transmission lens about a second axis, the second axis is parallel to the micro-LED array area in a second direction, and the second axis is not parallel to the first axis.

48. The micro-LED display panel according to clause 47, wherein the first axis is perpendicular to the second axis.

49. The micro-LED display panel according to clause 47 or 48, wherein the transmission lens assembly further comprises:
a first frame;
a second frame provided inside the first frame and connected with the first frame by a first pair of connecting bridges along the first axis; and
a third frame provided inside the second frame and connected with the second frame by a second pair of connecting bridges along the second axis;
wherein the transmission lens is supported by the third frame and configured to be rotated with the third frame.

50. The micro-LED display panel according to clause 49, wherein the holder is configured to support the transmission lens assembly by supporting the first frame.

51. The micro-LED display panel according to any one of clauses 43 to 50, wherein when rotating, the transmission lens and the micro-LED array area do not contact each other.

52. The micro-LED display panel according to clause 51, wherein a distance between a bottom of the transmission lens and a top of micro-LED array area is not less than 1 μm.

53. The micro-LED display panel according to clause 43, wherein the lens position rotating actuator further comprises one or more magnetic elements provided between the transmission lens assembly and the micro-LED chip.

54. The micro-LED display panel according to clause 53, wherein the one or more magnetic elements are provided on the IC backplane and under an edge of the transmission lens assembly.

55. The micro-LED display panel according to clause 54, wherein the transmission lens assembly further comprises:
a first frame;
a second frame provided inside the first frame and connected with the first frame by a first pair of connecting bridges along a first axis; and
a third frame provided inside the second frame and connected with the second frame by a second pair of connecting bridges along a second axis;
wherein the transmission lens is supported by the third frame and configured to be rotated with the third frame.

56. The micro-LED display panel according to clause 55, wherein the one or more magnetic elements are provided under an edge of the first frame.

57. The micro-LED display panel according to clause 56, wherein a first one of the one or more magnetic elements is provided at a first edge of the IC backplane, and a second one of the one or more magnetic elements is provided at a second edge of the IC backplane, and the first edge is perpendicular to the second edge.

58. The micro-LED display panel according to clause 56, wherein a first one of the one or more magnetic elements is configured to generate a first magnetic field, and a second one of the one or more magnetic elements is configured to generate a second magnetic field, wherein the first magnetic field is perpendicular to the second magnetic field.

59. The micro-LED display panel according to clause 57 or 58, wherein the holder and the first and second magnetic elements are spaced apart.

60. The micro-LED display panel according to any one of clauses 57 to 59, wherein each of the first and second the magnetic elements is an electromagnetic coil or a capacitance magnetic element.

61. The micro-LED display panel according to any one of clauses 43 to 60, wherein one or more of the holders are provided at one or more corners of the IC backplane.

62. The micro-LED display panel according to any one of clauses 43 to 61, wherein a top of the holder is higher than a top of the micro-LED array area.

63. The micro-LED display panel according to any one of clauses 43 to 62, wherein the micro-LED display chip is an AM (active matrix) micro-LED display chip or PM (passive matrix) micro-LED display chip.

64. The micro-LED display panel according to any one of clauses 43 to 63, wherein a diagonal length of the micro-LED array area is not greater than 1 cm.

65. The micro-LED display panel according to any one of clauses 43 to 64, wherein a material of the transmission lens is inorganic-glass or resin glass.

66. The micro-LED display panel according to any one of clauses 43 to 65, wherein the micro-LED display panel is applied in a micro display device or a micro sensor.

67. The micro-LED display panel according to any one of clauses 43 to 66, wherein a diagonal length of the micro-LED display panel is not greater than 5 μm; and a diagonal length of the micro-LED array area is not greater than 5 cm.

68. The micro-LED display panel according to any one of clauses 43 to 67, wherein the transmission lens is an optical lens; and image light emitted from the micro-LED array area is transmitted through the transmission lens in a changeable direction corresponding to a rotating direction of the transmission lens.

69. The micro-LED display panel according to any one of clauses 43 to 68, wherein a diagonal length of the transmission lens is not less than a diagonal length of the micro-LED array area.

70. The micro-LED display panel according to any one of clauses 43 to 69, wherein the image light rotating element further comprises an actuator controller electrically connected with the lens position rotating actuator and configured to control a rotation direction and a rotating frequency of the transmission lens.

71. A micro display system comprising:
a micro-LED (light emitting diode) display panel comprising:
   a micro-LED display chip comprising a micro-LED array area and an IC (integrated circuit) backplane, wherein the micro-LED array area is provided on the IC backplane;
   an image light rotating element comprising:
      a transmission lens assembly provided above the micro-LED display chip and comprising a transmission lens over the micro-LED array area; and
      a lens position rotating actuator configured to rotate the transmission lens about at least one preset axis, wherein the at least one preset axis is parallel to the micro-LED array area;
   an external circuit plane provided at a bottom of the IC backplane and electrically connected with the IC backplane via a bonding wire; and
   a holder provided on the external circuit plane and configured to support the transmission lens assembly; and

a controlling unit connected with the IC backplane and the image light rotating element of the micro-LED display panel and configured to transmit objective image data to the IC backplane and the image light rotating element.

72. The micro display system according to clause 71, wherein the image light rotating element further comprises an actuator controller electrically connected with the lens position rotating actuator and configured to control a rotation direction and a rotating frequency of the lens position rotating actuator; and
the controlling unit is further connected with the actuator controller, and further configured to transmit signals to the IC backplane and the actuator controller.

73. The micro display system according to clause 71, wherein the controlling unit is further configured to process the objective image data to form N pieces of sub-image data, calculate a rotation direction and a rotating frequency of the transmission lens for each sub-image data according to a refresh frequency of the objective image data, send the rotation direction and the rotating frequency to the actuator controller, and send the sub-image data and the rotating frequency to the IC backplane; wherein N is an integer not less than two;
the actuator controller is configured to receive the rotation direction and the rotating frequency of the transmission lens for each piece of the sub-image data, and control the lens position rotating actuator and the transmission lens to perform a rotating process based on the rotation direction and the rotating frequency for each piece of the sub-image data; and
the IC backplane is configured to synchronously control the micro-LED array area to display a sub-image according to the sub-image data and the rotating frequency.

74. The micro display system according to clause 73, wherein each of pixel points in the micro-LED array area is separately formed in a corresponding pixel area, each of the pixel areas comprises N pieces of pixel sub-images, the pixel sub-images of a pixel point are shifted in a shifting order and in the pixel area of the pixel point, and the N pieces of pixel sub-images are shifted in a same shifting order with the pixel sub-images.

75. The micro display system according to clause 74, wherein the rotating frequency of sub-image data is M times the refresh frequency of the objective image data, M being an integer and not less than two.

76. The micro display system according to clause 75, wherein N is an even integer, and M is equal to N.

77. The micro display system according to clause 75 or 76, wherein the rotating frequency of the transmission lens is four times the refresh frequency of the objective image data.

78. The micro display system according to any one of clauses 75 to 77, wherein the refresh frequency of the objective image data is 50˜70 Hz.

79. The micro display system according to clauses 75 to 78, wherein a shifting direction is a clockwise direction.

80. The micro display system according to clause 74, wherein sub-images formed by the sub-image data are the same as the objective image formed by the objective image data.

81. The micro display system according to clause 80, wherein a gray-scale of at least one of the pixel sub-images of the same pixel point is not the same as a gray-scale of the objective image of the same pixel point in the objective image data.

82. The micro display system according to clause 80, wherein a gray-scale of all of the pixel sub-images of the same pixel point is as same as a gray-scale of the objective image of the same pixel point in the objective image data.

83. The micro display system according to clause 80, wherein a relationship of a shifting distance of the sub-image from the objective image and a rotation angle of the transmission lens about an axis is

$$Δ y = t sin θ ( 1 - \sqrt{\frac{1 - {sin}^{2} θ}{{n}^{2} - {sin}^{2} θ}} ) ;$$

wherein Δy is the shifting distance, θ is the rotation angle, t is a center thickness of the transmission lens, and n is a refraction ratio of the transmission lens.

84. The micro display system according to clause 83, wherein the shifting distance between adjacent pixel sub-images is 50˜100% of a pixel pitch.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro-LED (light emitting diode) display panel comprising:
a micro-LED display chip comprising a micro-LED array area and an IC (integrated circuit) backplane, wherein the micro-LED array area is provided on the IC backplane;
an image light rotating element comprising:
a transmission lens assembly provided above the micro-LED display chip and comprising a transmission lens over the micro-LED array area; and
a lens position rotating actuator configured to rotate the transmission lens about at least one preset axis, wherein the at least one preset axis is parallel to the micro-LED array area; and
a holder provided on the micro-LED display chip and configured to support the transmission lens assembly.

2. The micro-LED display panel according to claim 1, wherein the holder is provided on the IC backplane.

3. The micro-LED display panel according to claim 2, wherein the holder is configured to support the transmission lens assembly at an edge of the transmission lens assembly.

4. The micro-LED display panel according to claim 1, wherein the preset axis is a first axis, wherein the first axis is parallel to the micro-LED array area in a first direction.

5. The micro-LED display panel according to claim 4, wherein the lens position rotating actuator is further configured to rotate the transmission lens about a second axis, wherein the second axis is parallel to the micro-LED array area in a second direction, and the second axis is not parallel to the first axis.

6. The micro-LED display panel according to claim 5, wherein the first axis is perpendicular to the second axis.

7. The micro-LED display panel according to claim 5, wherein the transmission lens assembly further comprises:
a first frame;
a second frame provided inside the first frame and connected with the first frame by a first pair of connecting bridges along the first axis; and
a third frame provided inside the second frame and connected with the second frame by a second pair of connecting bridges along the second axis;
wherein the transmission lens is supported by the third frame and configured to be rotated with the third frame.

8. The micro-LED display panel according to claim 7, wherein the holder is configured to support the transmission lens assembly by supporting the first frame.

9. The micro-LED display panel according to claim 1, wherein, when rotating, the transmission lens and the micro-LED array area do not contact each other.

10. The micro-LED display panel according to claim 9, wherein a distance between a bottom of the transmission lens and a top of micro-LED array area is not less than 1 μm.

11. The micro-LED display panel according to claim 1, wherein the lens position rotating actuator further comprises one or more magnetic elements provided between the transmission lens assembly and the micro-LED chip.

12. The micro-LED display panel according to claim 11, wherein the one or more magnetic elements are provided on the IC backplane and under an edge of the transmission lens assembly.

13. The micro-LED display panel according to claim 12, wherein the transmission lens assembly further comprises:
a first frame;
a second frame provided inside the first frame and connected with the first frame by a first pair of connecting bridges along a first axis; and
a third frame provided inside the second frame and connected with the second frame by a second pair of connecting bridges along a second axis;
wherein the transmission lens is supported by the third frame and configured to be rotated with the third frame.

14. The micro-LED display panel according to claim 13, wherein the one or more magnetic elements are provided under an edge of the first frame.

15. The micro-LED display panel according to claim 14, wherein a first one of the one or more magnetic elements is provided at a first edge of the IC backplane, a second one of the one or more magnetic elements is provided at a second edge of the IC backplane, and the first edge is perpendicular to the second edge.

16. The micro-LED display panel according to claim 14, wherein a first one of the one or more magnetic element is configured to generate a first magnetic field, a second one of the one or more magnetic elements is configured to generate a second magnetic field, wherein the first magnetic field is perpendicular to the second magnetic field.

17. The micro-LED display panel according to claim 16, wherein the holder and the first and second magnetic elements are spaced apart.

18. The micro-LED display panel according to claim 17, wherein each of the first and second magnetic elements is an electromagnetic coil or a capacitance magnetic element.

19. The micro-LED display panel according to claim 1, wherein one or more of the holders are provided at one or more corners of the IC backplane.

20. The micro-LED display panel according to claim 1, wherein a top of the holder is higher than a top of the micro-LED array area.

21. The micro-LED display panel according to claim 1, wherein the micro-LED display chip is an AM (active matrix) micro-LED display chip or PM (passive matrix) micro-LED display chip.

22. The micro-LED display panel according to claim 1, wherein a diagonal length of the micro-LED array area is not greater than 1 cm.

23. The micro-LED display panel according to claim 1, wherein a material of the transmission lens is inorganic-glass or resin glass.

24. The micro-LED display panel according to claim 1, wherein the micro-LED display panel is applied in a micro display device or a micro sensor.

25. The micro-LED display panel according to claim 1, wherein a diagonal length of the micro-LED display panel is not greater than 5 μm; and a diagonal length of the micro-LED array area is not greater than 5 cm.

26. The micro-LED display panel according to claim 1, wherein the transmission lens is an optical lens; and image light emitted from the micro-LED array area is transmitted through the transmission lens in a changeable direction corresponding to a rotating direction of the transmission lens.

27. The micro-LED display panel according to claim 1, wherein a diagonal length of the transmission lens is not less than a diagonal length of the micro-LED array area.

28. The micro-LED display panel according to claim 1, wherein the image light rotating element further comprises an actuator controller electrically connected with the lens position rotating actuator and configured to control a rotation direction and a rotating frequency of the transmission lens.

29. A micro display system comprising:
a micro-LED (light emitting diode) display panel comprising
a micro-LED display chip comprising a micro-LED array area and an IC (integrated circuit) backplane, wherein the micro-LED array area is provided on the IC backplane;
an image light rotating element comprising:
a transmission lens assembly provided above the micro-LED display chip and comprising a transmission lens over the micro-LED array area; and
a lens position rotating actuator configured to rotate the transmission lens about at least one preset axis, wherein the at least one preset axis is parallel to the micro-LED array area; and
a holder provided on the micro-LED display chip and configured to support the transmission lens assembly; and
a controlling unit connected with the IC backplane and the image light rotating element of the micro-LED display panel and configured to transmit objective image data to the IC backplane and the image light rotating element.

30. The micro display system according to claim 29, wherein the image light rotating element further comprises an actuator controller electrically connected with the lens position rotating actuator and configured to control a rotation direction and a rotating frequency of the lens position rotating actuator; and
the controlling unit is further connected with the actuator controller, and further configured to transmit signals to the IC backplane and the actuator controller.

31. The micro display system according to claim 29, wherein the controlling unit is further configured to process the objective image data to form N pieces of sub-image data, calculate a rotation direction and a rotating frequency of the transmission lens for each sub-image data according to a refresh frequency of the objective image data, send the rotation direction and the rotating frequency to the actuator controller, and send the sub-image data and the rotating frequency to the IC backplane; wherein N is an integer not less than two;
the actuator controller is configured to receive the rotation direction and the rotating frequency of the transmission lens for each piece of the sub-image data, and control the lens position rotating actuator and the transmission lens to perform a rotating process based on the rotation direction and the rotating frequency for each piece of the sub-image data; and
the IC backplane is configured to synchronously control the micro-LED array area to display a sub-image according to the sub-image data and the rotating frequency.

32. The micro display system according to claim 31, wherein each of pixel points in the micro-LED array area is separately formed in a corresponding pixel area, each of the pixel areas comprises N pieces of pixel sub-images, the pixel sub-images of a pixel point are shifted in a shifting order and in the pixel area of the pixel point, and the N pieces of pixel sub-images are shifted in a same shifting order with the pixel sub-images.

33. The micro display system according to claim 32, wherein the rotating frequency of sub-image data is M times the refresh frequency of the objective image data, wherein M being an integer not less than two.

34. The micro display system according to claim 33, wherein N is an even integer, and M is equal to N.

35. The micro display system according to claim 33, wherein the rotating frequency of the transmission lens is four times the refresh frequency of the objective image data.

36. The micro display system according to claim 35, wherein the refresh frequency of the objective image data is 50˜70 Hz.

37. The micro display system according to claim 33, wherein a shifting direction is a clockwise direction.

38. The micro display system according to claim 32, wherein sub-images formed by the sub-image data are the same as the objective image formed by the objective image data.

39. The micro display system according to claim 38, wherein a gray-scale of at least one of the pixel sub-images of the same pixel point is not the same as a gray-scale of the objective image of the same pixel point in the objective image data.

40. The micro display system according to claim 38, wherein a gray-scale of all of the pixel sub-images of the same pixel point is as same as a gray-scale of the objective image of the same pixel point in the objective image data.

41. The micro display system according to claim 38, wherein a relationship of a shifting distance of the sub-image from the objective image and a rotation angle of the transmission lens about an axis is
$$Δ y = t sin θ ( 1 - \sqrt{\frac{1 - {sin}^{2} θ}{{n}^{2} - {sin}^{2} θ}} ) ;$$
wherein Δy is the shifting distance, θ is the rotation angle, t is a center thickness of the transmission lens, and n is a refraction ratio of the transmission lens.

42. The micro display system according to claim 41, wherein the shifting distance between adjacent pixel sub-images is 50˜100% of a pixel pitch.

43. A micro-LED (light emitting diode) display panel comprising:
a micro-LED display chip comprising a micro-LED array area and an IC (integrated circuit) backplane, wherein the micro-LED array area is provided on the IC backplane;
an image light rotating element comprising:
a transmission lens assembly provided above the micro-LED display chip and comprising a transmission lens over the micro-LED array area; and
a lens position rotating actuator configured to rotate the transmission lens about at least one preset axis, wherein the at least one preset axis is parallel to the micro-LED array area;
an external circuit plane provided at a bottom of the IC backplane and electrically connected with the IC backplane via a bonding wire; and
a holder provided on the external circuit plane and configured to support the transmission lens assembly.

44. The micro-LED display panel according to claim 43, wherein the external circuit plane comprises a flexible printed circuit.

45. The micro-LED display panel according to claim 43, wherein the holder is configured to support the transmission lens assembly at an edge of the transmission lens assembly.

46. The micro-LED display panel according to claim 43, wherein the preset axis is a first axis, and the first axis is parallel to the micro-LED array area in a first direction.

47. The micro-LED display panel according to claim 46, wherein the lens position rotating actuator is further configured to rotate the transmission lens about a second axis, the second axis is parallel to the micro-LED array area in a second direction, and the second axis is not parallel to the first axis.

48. The micro-LED display panel according to claim 47, wherein the first axis is perpendicular to the second axis.

49. The micro-LED display panel according to claim 47, wherein the transmission lens assembly further comprises:
a first frame;
a second frame provided inside the first frame and connected with the first frame by a first pair of connecting bridges along the first axis; and
a third frame provided inside the second frame and connected with the second frame by a second pair of connecting bridges along the second axis;
wherein the transmission lens is supported by the third frame and configured to be rotated with the third frame.

50. The micro-LED display panel according to claim 49, wherein the holder is configured to support the transmission lens assembly by supporting the first frame.

51. The micro-LED display panel according to claim 43, wherein when rotating, the transmission lens and the micro-LED array area do not contact each other.

52. The micro-LED display panel according to claim 51, wherein a distance between a bottom of the transmission lens and a top of micro-LED array area is not less than 1 μm.

53. The micro-LED display panel according to claim 43, wherein the lens position rotating actuator further comprises one or more magnetic elements provided between the transmission lens assembly and the micro-LED chip.

54. The micro-LED display panel according to claim 53, wherein the one or more magnetic elements are provided on the IC backplane and under an edge of the transmission lens assembly.

55. The micro-LED display panel according to claim 54, wherein the transmission lens assembly further comprises:
a first frame;
a second frame provided inside the first frame and connected with the first frame by a first pair of connecting bridges along a first axis; and
a third frame provided inside the second frame and connected with the second frame by a second pair of connecting bridges along a second axis;
wherein the transmission lens is supported by the third frame and configured to be rotated with the third frame.

56. The micro-LED display panel according to claim 55, wherein the one or more magnetic elements are provided under an edge of the first frame.

57. The micro-LED display panel according to claim 56, wherein a first one of the one or more magnetic elements is provided at a first edge of the IC backplane, and a second one of the one or more magnetic elements is provided at a second edge of the IC backplane, and the first edge is perpendicular to the second edge.

58. The micro-LED display panel according to claim 56, wherein a first one of the one or more magnetic elements is configured to generate a first magnetic field, and a second one of the one or more magnetic elements is configured to generate a second magnetic field, wherein the first magnetic field is perpendicular to the second magnetic field.

59. The micro-LED display panel according to claim 57, wherein the holder and the first and second magnetic elements are spaced apart.

60. The micro-LED display panel according to claim 57, wherein each of the first and second the magnetic elements is an electromagnetic coil or a capacitance magnetic element.

61. The micro-LED display panel according to claim 43, wherein one or more of the holders are provided at one or more corners of the IC backplane.

62. The micro-LED display panel according to claim 43, wherein a top of the holder is higher than a top of the micro-LED array area.

63. The micro-LED display panel according to claim 43, wherein the micro-LED display chip is an AM (active matrix) micro-LED display chip or PM (passive matrix) micro-LED display chip.

64. The micro-LED display panel according to claim 43, wherein a diagonal length of the micro-LED array area is not greater than 1 cm.

65. The micro-LED display panel according to claim 43, wherein a material of the transmission lens is inorganic-glass or resin glass.

66. The micro-LED display panel according to claim 43, wherein the micro-LED display panel is applied in a micro display device or a micro sensor.

67. The micro-LED display panel according to claim 43, wherein a diagonal length of the micro-LED display panel is not greater than 5 μm; and a diagonal length of the micro-LED array area is not greater than 5 cm.

68. The micro-LED display panel according to claim 43, wherein the transmission lens is an optical lens; and image light emitted from the micro-LED array area is transmitted through the transmission lens in a changeable direction corresponding to a rotating direction of the transmission lens.

69. The micro-LED display panel according to claim 43, wherein a diagonal length of the transmission lens is not less than a diagonal length of the micro-LED array area.

70. The micro-LED display panel according to claim 43, wherein the image light rotating element further comprises an actuator controller electrically connected with the lens position rotating actuator and configured to control a rotation direction and a rotating frequency of the transmission lens.

71. A micro display system comprising:
a micro-LED (light emitting diode) display panel comprising:
a micro-LED display chip comprising a micro-LED array area and an IC (integrated circuit) backplane, wherein the micro-LED array area is provided on the IC backplane;
an image light rotating element comprising:
a transmission lens assembly provided above the micro-LED display chip and comprising a transmission lens over the micro-LED array area; and
a lens position rotating actuator configured to rotate the transmission lens about at least one preset axis, wherein the at least one preset axis is parallel to the micro-LED array area;
an external circuit plane provided at a bottom of the IC backplane and electrically connected with the IC backplane via a bonding wire; and
a holder provided on the external circuit plane and configured to support the transmission lens assembly; and
a controlling unit connected with the IC backplane and the image light rotating element of the micro-LED display panel and configured to transmit objective image data to the IC backplane and the image light rotating element.

72. The micro display system according to claim 71, wherein the image light rotating element further comprises an actuator controller electrically connected with the lens position rotating actuator and configured to control a rotation direction and a rotating frequency of the lens position rotating actuator; and
the controlling unit is further connected with the actuator controller, and further configured to transmit signals to the IC backplane and the actuator controller.

73. The micro display system according to claim 71, wherein the controlling unit is further configured to process the objective image data to form N pieces of sub-image data, calculate a rotation direction and a rotating frequency of the transmission lens for each sub-image data according to a refresh frequency of the objective image data, send the rotation direction and the rotating frequency to the actuator controller, and send the sub-image data and the rotating frequency to the IC backplane; wherein N is an integer not less than two;
the actuator controller is configured to receive the rotation direction and the rotating frequency of the transmission lens for each piece of the sub-image data, and control the lens position rotating actuator and the transmission lens to perform a rotating process based on the rotation direction and the rotating frequency for each piece of the sub-image data; and
the IC backplane is configured to synchronously control the micro-LED array area to display a sub-image according to the sub-image data and the rotating frequency.

74. The micro display system according to claim 73, wherein each of pixel points in the micro-LED array area is separately formed in a corresponding pixel area, each of the pixel areas comprises N pieces of pixel sub-images, the pixel sub-images of a pixel point are shifted in a shifting order and in the pixel area of the pixel point, and the N pieces of pixel sub-images are shifted in a same shifting order with the pixel sub-images.

75. The micro display system according to claim 74, wherein the rotating frequency of sub-image data is M times the refresh frequency of the objective image data, M being an integer and not less than two.

76. The micro display system according to claim 75, wherein N is an even integer, and M is equal to N.

77. The micro display system according to claim 75, wherein the rotating frequency of the transmission lens is four times the refresh frequency of the objective image data.

78. The micro display system according to claim 75, wherein the refresh frequency of the objective image data is 50˜70 Hz.

79. The micro display system according to claim 75, wherein a shifting direction is a clockwise direction.

80. The micro display system according to claim 74, wherein sub-images formed by the sub-image data are the same as the objective image formed by the objective image data.

81. The micro display system according to claim 80, wherein a gray-scale of at least one of the pixel sub-images of the same pixel point is not the same as a gray-scale of the objective image of the same pixel point in the objective image data.

82. The micro display system according to claim 80, wherein a gray-scale of all of the pixel sub-images of the same pixel point is as same as a gray-scale of the objective image of the same pixel point in the objective image data.

83. The micro display system according to claim 80, wherein a relationship of a shifting distance of the sub-image from the objective image and a rotation angle of the transmission lens about an axis is
$$Δ y = t sin θ ( 1 - \sqrt{\frac{1 - {sin}^{2} θ}{{n}^{2} - {sin}^{2} θ}} ) ;$$
wherein Δy is the shifting distance, θ is the rotation angle, t is a center thickness of the transmission lens, and n is a refraction ratio of the transmission lens.

84. The micro display system according to claim 83, wherein the shifting distance between adjacent pixel sub-images is 50˜100% of a pixel pitch.
